(19) United States
(12) Patent Application Publication
(10) Pub. No.: US 2024/0222386 A1
(43) Pub. Date: Jul. 4, 2024

(54) DISPLAY DEVICE AND METHOD OF MANUFACTURING THE SAME

(71) Applicant: SILICON DISPLAY TECHNOLOGY, Yongin-si (KR)

(72) Inventors: Jiwon PARK, Yongin-si (KR); Hyunwoo KIM, Yongin-si (KR); Jae Ho SHIN, Yongin-si (KR); Jin Hyeong YU, Yongin-si (KR)

(21) Appl. No.: 18/397,041

(22) Filed: Dec. 27, 2023

(30) Foreign Application Priority Data
Dec. 28, 2022 (KR) 10-2022-0187856
Oct. 12, 2023 (KR) 10-2023-0136121

(51) Int. Cl. H01L 27/12; H01L 25/16

(52) U.S. Cl. CPC H01L 27/124; H01L 25/167; H01L 27/1259

(57) ABSTRACT

A display device includes: a first-color light emitting diode (LED); thin film transistors (TFTs) and wires located on the first-color LED; a second-color LED located in a first area on the TFTs and the wires; a third-color LED located in a second area on the TFTs and the wires; a plurality of wires located between the first area and the second area; and a plurality of pads connected to the plurality of wires.

### CROSS-REFERENCE TO RELATED APPLICATION

This application claims priority to and the benefit of Korean Patent Application No. 10-2022-0187856 filed in the Korean Intellectual Property Office on Dec. 28, 2022, and Korean Patent Application No. 10-2023-0136121 filed in the Korean Intellectual Property Office on Oct. 12, 2023, the entire contents of which are incorporated herein by reference.

### BACKGROUND

### (a) Technical Field

The present disclosure relates to a pixel package structure used in manufacturing an LED display. Particularly, the present disclosure relates to a display using a micro-LED (μLED).

### (b) Description of the Related Art

FIG. 1 is a circuit diagram illustrating a structure of a subpixel.

FIG. 2 is a diagram schematically illustrating a structure of an RGB pixel.

As illustrated in FIG. 1, one subpixel may include two thin film transistors TFT A and TFT B (TFTs), one capacitor CAP, and a μLED, which is a light emitting device.

To produce a typical RGB-configuration μLED display, one pixel is formed by transferring three LEDs, which are red, green, and blue LEDs. For example, as illustrated in FIG. 2, in a pixel structure for active matrix (AM) driving, a TFT A and a TFT B for AM driving may be formed on a backplane substrate, and red, green, and blue LEDs may be transferred on the substrate to form one pixel.

### SUMMARY

The present disclosure attempts to provide a display device and a method of manufacturing the same capable of improving transfer difficulty.

In producing a μLED display, a pixel is formed using a modular package to emit multiple colors rather than a single color. The package includes R, G, and B LEDs and TFTs for AM driving, enabling AM driving by simply attaching the package to a backplane where only gate and data lines exist.

An exemplary embodiment of the present disclosure provides a display device including: a first-color light emitting diode (LED); a circuit layer located on the first-color LED and including a plurality of thin film transistors (TFTs) and a plurality of first wires; a second-color LED located in a first area on the circuit layer; a third-color LED located in a second area on the circuit layer; a plurality of second wires located between the first area and the second area; and a plurality of pads connected to the plurality of second wires.

The display device may further include a passivation layer located on the second-color LED, the third-color LED, and the circuit layer, wherein the plurality of pads are formed and located on the passivation layer.

The plurality of TFTs and the plurality of first wires may include at least two TFTs and two first wires for driving the first-color LED, and the two first wires may be connected to two electrodes of the first-color LED, respectively.

The plurality of TFTs and the plurality of first wires may include at least two TFTs and two first wires for driving the second-color LED. The two first wires may be connected to two electrodes of the second-color LED, respectively.

The plurality of TFTs and the plurality of first wires may include at least two TFTs and two first wires for driving the third-color LED. The two first wires may be connected to two electrodes of the third-color LED, respectively.

The first-color LED may overlap with the first area in a vertical direction, and the first-color LED may overlap with the second area in the vertical direction. The first-color LED may not overlap with the first area and the second area in a vertical direction.

The plurality of pads may include: two pads through which a gate signal and a data signal are supplied to the first-color LED; two pads through which a gate signal and a data signal are supplied to the second-color LED; two pads through which a gate signal and a data signal are supplied to the third-color LED; and two pads through which two power supply voltages are supplied.

Another exemplary embodiment of the present disclosure provides a method of manufacturing a display device including: forming a first LED; forming a circuit layer including a plurality of TFTs and a plurality of first wires on the first LED; forming a second LED in a first area of the circuit layer and forming a third LED in a second area of the circuit layer; forming a passivation layer on the second LED, the third LED, and the circuit layer; and forming a plurality of second wires in the passivation layer.

The method may further include forming a plurality of pads connected to the plurality of second wires on the passivation layer.

Using the present disclosure, it is possible to produce an AM μLED display with improved pixel density. The present disclosure provides a module in which RGB LEDs are packaged, capable of improving transfer difficulty as compared to that in a case where a μLED display is made by transferring LEDs separately.

### BRIEF DESCRIPTION OF THE DRAWINGS

FIG. 1 is a circuit diagram illustrating a structure of a subpixel.

FIG. 2 is a diagram schematically illustrating a structure of an RGB pixel.

FIG. 3 is a diagram illustrating an example in which LEDs for three colors and a TFT circuit are modularized into a package.

FIG. 4 is a diagram schematically illustrating light emission directions of the LEDs illustrated in FIG. 3.

FIGS. 5A and 5B are diagrams illustrating electrodes in cross-sectional structures of TFTs and wires illustrated in FIG. 3.

FIGS. 6 to 10 are process diagrams illustrating a method of manufacturing a package according to an exemplary embodiment.

FIG. 11 is a diagram illustrating a cross section of a package structure according to an exemplary embodiment.

FIG. 12 is a diagram illustrating cross sections of LED portions and other portions in FIG. 11.

FIG. 13 is a circuit diagram of a subpixel structure according to an exemplary embodiment.

FIG. 14 is a plan view illustrating an upper end of a package according to an exemplary embodiment.

FIG. 15 is a diagram illustrating a package structure according to an exemplary embodiment.

FIG. 16 is a diagram for explaining a method of manufacturing a package.

FIG. 17 is a diagram for explaining a method of manufacturing a package.

FIG. 18 is a diagram illustrating various TFT structures.

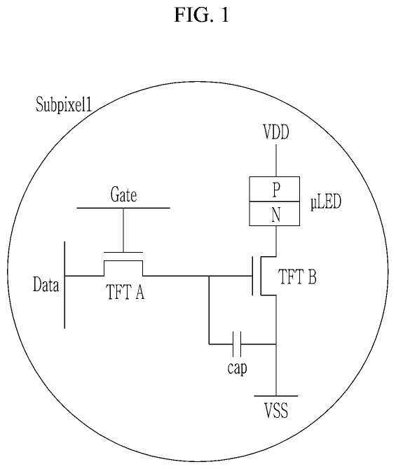

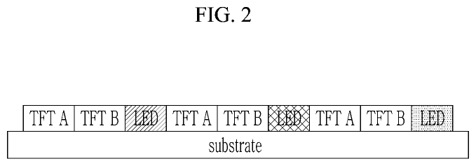

### DETAILED DESCRIPTION OF THE EMBODIMENTS

In the present disclosure, a TFT circuit for AM driving and red, green, and blue LEDs can be modularized into one package, thereby improving transfer difficulty and pixel density in manufacturing a μLED display.

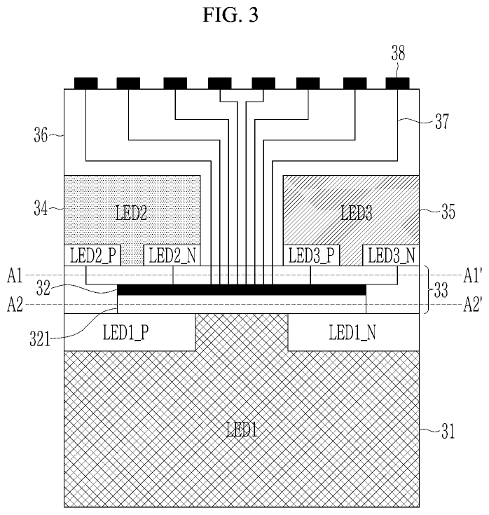

FIG. 3 is a diagram illustrating an example in which LEDs for three colors and a TFT circuit are modularized into a package.

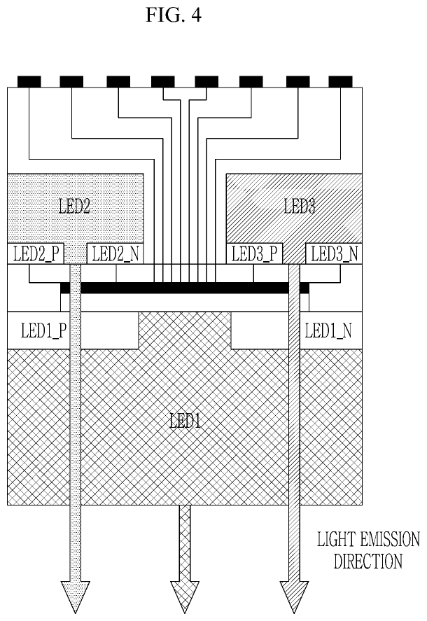

FIG. 4 is a diagram schematically illustrating light emission directions of the LEDs illustrated in FIG. 3.

As illustrated in FIG. 3, all of R, G, and B beams can be emitted in a single package module, and TFTs equipped for AM driving enable AM driving.

A method of manufacturing the package illustrated in FIG. 3 is as follows.

First, a LED1 layer 31 can be fabricated. The LED1 layer 31 may be manufactured by forming a material such as GaN or GaAs on a sapphire substrate. A TFT process may be performed on the manufactured LED1 layer 31 to form a TFT layer 32 including a driving TFT and wires (e.g., 321) connecting the TFT layer 32 and LED elements. The wire 321 may be a metal wire. A layer including the TFT layer 32 and the wire 321 will be referred to as a circuit layer 33. A LED2 34 and a LED3 35, which are manufactured separately, may be stacked on the circuit layer 33 by welding. After stacking the LED2 34 and the LED3 35, a passivation layer 36 may be formed, a plurality of wires (e.g., 37) required to drive the LED1, the LED2, and the LED3 may be formed in the passivation layer 36, and a plurality of electrode pads (e.g., 38) may be formed on the passivation layer 36. Each of the plurality of wires 37 may be electrically connected to a corresponding one of the plurality of electrode pads 38.

In the LED stacking scheme or structure as illustrated in FIG. 3, the circuit layer 33 including TFTs and wires may be stacked on the LED1 layer 31, which is a green LED, and the LED2 34, which is a blue LED, and the LED3 35, which is a red LED, on the circuit layer 33. Meanwhile, the colors of the LED1, the LED2, and the LED3 illustrated in FIG. 3 are merely examples, and the color arrangement may be changed. A back surface of the LED1 layer 31 is attached to one surface of the circuit layer 33 to face each other. Front surfaces of the LED2 34 and the LED3 35 are attached to the other surface of the circuit layer 33 to face each other. That is, the forward direction of the LED2 34 and the LED3 35 is the same as the backward direction of the LED1 layer 31.

As illustrated in FIG. 4, the light emission direction of the LED1 layer 31 may be backward, and the light emission directions of the LED2 34 and the LED3 35 may be forward.

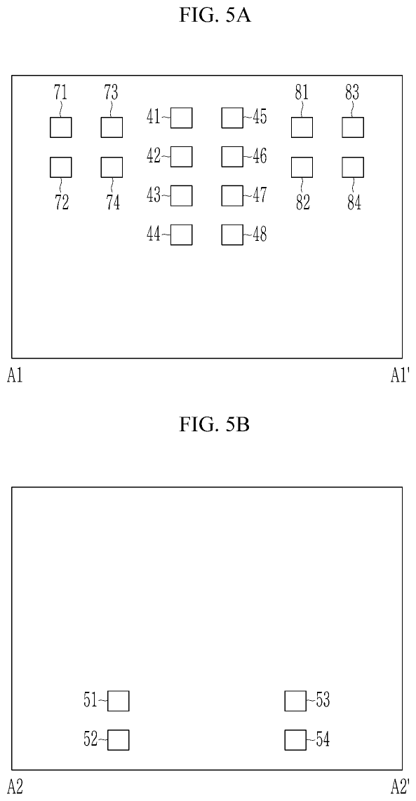

FIGS. 5A and 5B are diagrams illustrating electrodes in cross-sectional structures of the TFTs and the wires illustrated in FIG. 3.

FIG. 5A illustrates electrodes in a cross-sectional structure taken along A1-A1′ in FIG. 3. FIG. 5B illustrates electrodes in a cross-sectional structure taken along A2-A2′ in FIG. 3.

A plurality of electrodes 41 to 48 are electrodes connected to a plurality of pads located at an upper end of the package illustrated in FIG. 3. A plurality of electrodes 51 to 54 are electrodes connected to the LED1 layer 31, a plurality of electrodes 71 to 74 are electrodes connected to the LED2 34, and a plurality of electrodes 81 to 84 are electrodes connected to the LED3 35. The electrodes 51 and 52 may be connected to a positive terminal LED1-P corresponding to an anode electrode of an LED element in the LED1 layer 31. The electrodes 53 and 54 may be connected to a negative terminal LED1-N corresponding to a cathode electrode of the LED element in the LED1 layer 31. The electrodes 71 and 72 may be connected to a positive terminal LED2-P corresponding to an anode electrode of an LED element in the LED2 34. The electrodes 73 and 74 may be connected to a negative terminal LED2-N corresponding to a cathode electrode of the LED element in the LED2 34. The electrodes 81 and 82 may be connected to a positive terminal LED3-P corresponding to an anode electrode of an LED element in the LED3 35. The electrodes 83 and 84 may be connected to a negative terminal LED3-N corresponding to a cathode electrode of the LED element in the LED3 35.

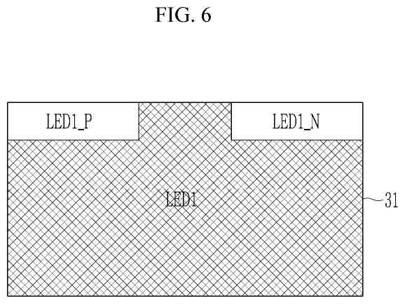

FIGS. 6 to 10 are process diagrams illustrating a method of manufacturing a package according to an exemplary embodiment.

As illustrated in FIG. 6, an LED1 layer 31 may be formed. The LED1 layer 31 may be implemented with a GaN LED. Although not illustrated in FIG. 6, the GaN LED may be implemented with a p-doped GaN layer (“p-GaN layer”), an n-doped GaN layer (“n-GaN layer”), an n-GaN layer, and an active layer between the n-GaN layer and the p-GaN layer. The LED1 layer 31 may include two contact electrodes LED1_P and LED1_N, the contact electrode LED1_P may be electrically connected to the p-GaN layer, and the contact electrode LED1_N may be electrically connected to the n-GaN layer. The LED is a diode that includes an anode and a cathode in circuitry, and the contact electrode LED1_P may be connected to the anode, and the contact electrode LED1_N may be connected to the cathode.

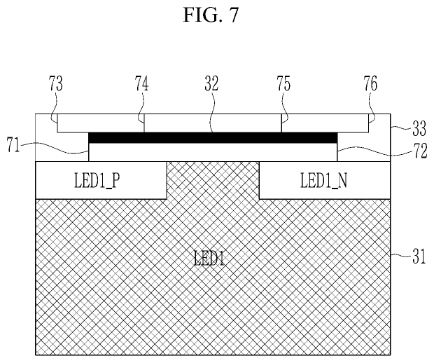

As illustrated in FIG. 7, TFTs and wires may be formed on the LED1.

As illustrated in FIG. 7, a plurality of wires 71 to 76 electrically connected to the TFT layer 32 may be formed. The shapes of the wires 71 to 76 illustrated in FIG. 7 are intended to show electrical connection between the TFT layer 32 and the LED1 to the LED3, and may differ from the actual shapes.

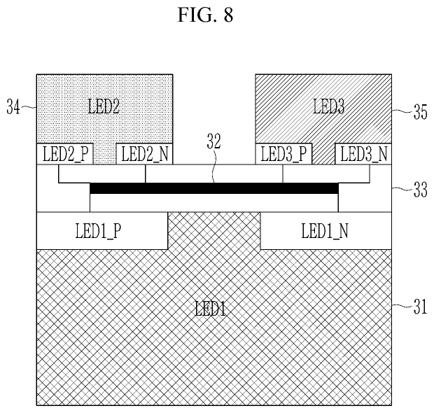

As illustrated in FIG. 8, on the circuit layer 33, an LED2 34 may be formed in a first area, and an LED3 35 may be formed in a second area separated from the first area. The LED2 34 may include two contact electrodes LED2_P and LED2_N, and the LED3 35 may include two contact electrodes LED3_P and LED3_N. The TFT layer 32 may be connected to the six contact electrodes LED1_P, LED1_N, LED2_P, LED2_N, LED3_P, and LED3_N through the plurality of wires 71 to 76.

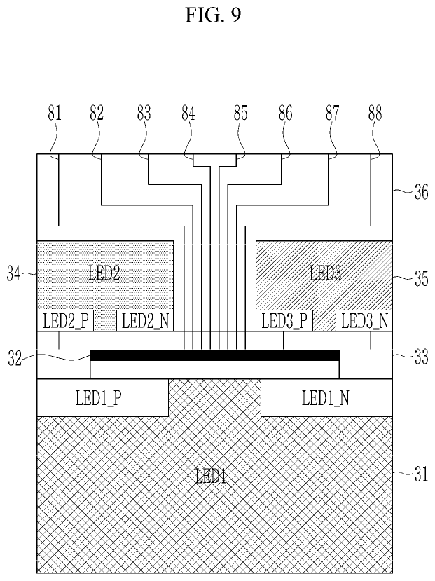

As illustrated in FIG. 9, a passivation layer 36 may be formed on the LED2 34, the LED3 35, and the circuit layer 33, and a plurality of wires 81 to 88 may be formed therein. For example, the passivation layer 36 may be formed on the LED2 34, the LED3 35, and the circuit layer 33 between the LED2 34 and the LED3 35. The shapes of the plurality of wires 81 to 88 illustrated in FIG. 9 are intended to show electrical connection to the TFTs 32, and may differ from the actual shapes.

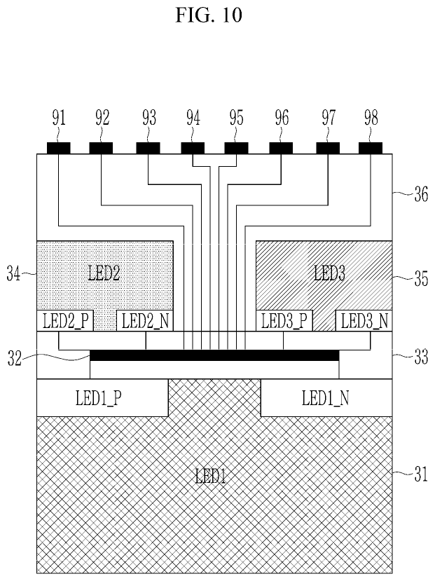

As illustrated in FIG. 10, a plurality of pads 91 to 98 corresponding to the plurality of wires 81 to 88, respectively, may be formed and positioned on the passivation layer 36.

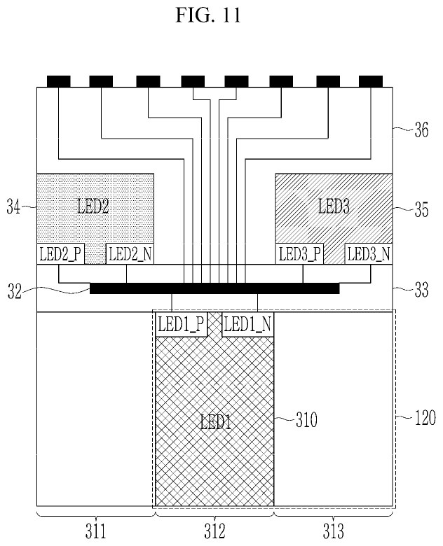

FIG. 11 is a diagram illustrating a cross section of a package structure according to an exemplary embodiment

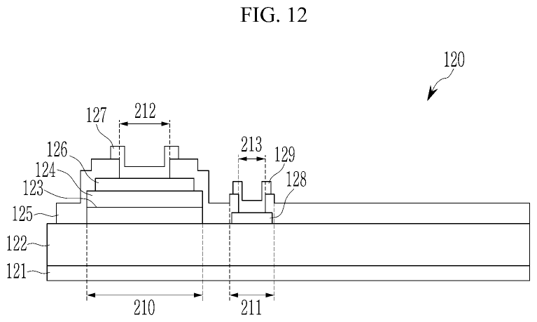

FIG. 12 is a view illustrating a partial area in FIG. 11 in detail.

In FIG. 11, unlike an exemplary embodiment of FIG. 3, an LED1 310 does not overlap with the LED2 34 and the LED3 35 in the vertical direction in cross-sectional view. Then, the light emission direction of the LED1 310 does not overlap with the light emission direction of each of the LED2 34 and the LED3 35, so that the light emission efficiency of the LED2 34 and the LED3 35 can be increased. For example, an area 311 where the LED2 34 is located, an area 312 where the LED1 310 is located, and an area 313 where the LED3 35 is located may be separated from each other.

FIG. 12 illustrates an area 120 in FIG. 11 in detail.

The LED1 310 may include a substrate 121, an n-GaN layer 122, an active layer 123, a p-GaN layer 124, a protective layer 125, a reflective film 126, a bonding pad 127, and a contact pad 128, and a bonding pad (129).

The substrate 121 may be implemented as a sapphire substrate. The n-GaN layer 122 may be formed and located on the substrate 121, the active layer 123 may be formed and located in an area 210 on the n-GaN layer 122, and the p-GaN layer 124 may be formed in the area 210 on the active layer 123, and the reflective film 126 may be formed and located on the p-GaN layer 124. The area 312 of FIG. 11 may include the area 210. The contact pad 128 may be formed and located in an area 211 on the n-GaN layer 122, and the area 313 in FIG. 11 may include the area 211. The protective film 125 may be formed and located on the n-GaN layer 122, the p-GaN layer 124, the reflective film 126, and the contact pad 128, via holes may be formed in areas 212 and 213 of the protective film 125, and the bonding pads 127 and 129 may be formed and located through the via holes. The bonding pad 127 may be the LED1_P electrode of FIG. 11 or may be connected to an LED1_P. The bonding pad 129 may be the LED1_N electrode of FIG. 11 or may be connected to an LED1_N. The bonding pads 127 and 129 may be connected to the TFT layer 32 through wires. Since the LED2 34 and the LED3 35 provide light by emitting light in a direction where the electrodes LED2_P, LED2_N, LED3_P, and LED3_N are located, the electrodes LED2_P, LED2_N, LED3_P, and LED3_N and/or electrodes connected to the electrodes LED2_P, LED2_N, LED3_P, and LED3_N may be transparent electrodes. Opaque metal electrodes may also be used, but in this case, it is required that an area occupied by the electrodes be small so as not to impede emission of light.

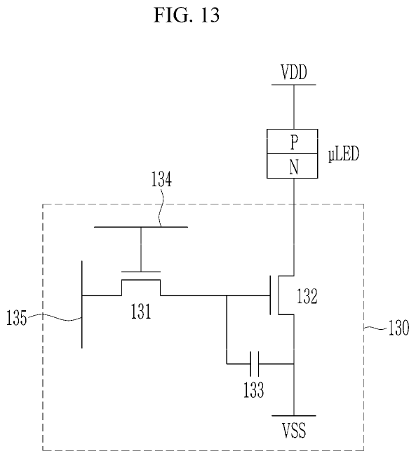

FIG. 13 is a circuit diagram of a subpixel structure according to an exemplary embodiment.

As illustrated in FIG. 13, a driving circuit 130 includes two TFTs 131 and 132 and a capacitor 133. The driving circuit 130 illustrated in FIG. 13 is an example, and a driving circuit that can be applied to drive a subpixel is not limited thereto.

A μLED connected to the driving circuit 130 may correspond to one of the LED1 to the LED3 in the cross-sectional views of FIGS. 3 and 11, etc. The TFT 131, which is a switching transistor, may include a gate connected to a gate line 134, and may perform a switching operation according to a gate signal provided through the gate line 134. A data line 135 to which a data voltage is supplied is connected to one end of the TFT 131. The other end of the TFT 131 is connected to a gate of the TFT 132, which is a driving transistor. One end of the TFT 132 may be connected to one end of the μLED, and VSS, which is a power supply voltage, may be supplied to the other end of the TFT 132. A capacitor 133 is connected between the gate and the other end of the TFT 132. VDD, which is a power supply voltage, may be supplied to the other end of the μLED.

The circuit layer 33 may include driving circuits and wirings for the LED1 31 or 310, the LED2 34, and the LED3 35 according to the exemplary embodiments illustrated in FIG. 3 or 11. The power supply voltages VSS and VDD required for driving the LED1 31 or 310, the LED2 34, and the LED3 35 may be provided through electrodes and/or wires in the circuit layer 33. The circuit layer 33 may be supplied with the power supply voltages VSS and VDD through corresponding ones of the plurality of pads (e.g., 91 to 98 in FIG. 10) located at the upper end. For example, the circuit layer 33 may include driving circuits for the LED1 31 or 310, the LED2 34, and the LED3 35, respectively, and wires connected to the driving circuits. A gate line and a data line for providing a gate signal and a data signal for driving the LED3 35 corresponding to a red subpixel, a gate line and a data line for providing a gate signal and a data signal for driving the LED2 34 corresponding to a blue subpixel, and a gate line and a data line for providing a gate signal and a data signal for driving the LED1 31 or 310 corresponding to a green subpixel may be connected to corresponding ones of the plurality of pads.

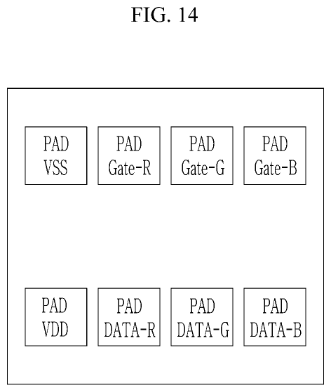

FIG. 14 is a plan view illustrating an upper end of a package according to an exemplary embodiment.

Gate signals may be supplied to gates of switching transistors (131 in FIG. 13) in respective driving circuits for the LED1 31 or 310, the LED2 34, and the LED3 35 through three pads PAD Gate-R, PAD Gate-G, and PAD Gate-B located at the upper end illustrated in FIG. 14. Data voltages may be supplied to the LED1 31 or 310, the LED2 34, and the LED3 35 through three pads PAD DATA-R, PAD DATA-G, and PAD DATA-B located at the upper end, respectively. When the switching transistor (131 in FIG. 13) of each driving circuit is turned on, a data voltage may be provided to the gate of the driving transistor (132 in FIG. 13) for each of the LED1 31 or 310, the LED2 34, and the LED3 35.

The power supply voltages VDD and VSS may be shared by a plurality of subpixels, and thus, wires for supplying the power supply voltages VDD and VSS may be connected to two pads PAD VDD and PAD VSS located at the upper end.

Although it is illustrated in FIG. 14 that the total number of electrode pads located at the upper end is 8, including two pads for supplying power voltages, the disclosure is not limited thereto. Power lines may be added to separately supply power supply voltages VDD and/or power supply voltages VSS for R, G, and B, and pads located at the upper end may be added accordingly. For example, in a case where supply power supply voltages VDD and power supply voltages VSS for R, G, and B are all supplied separately, four pads may be added, and as a result, the total number of electrode pads at the upper end may be 12. The number of pads is not limited to 8 or 12, because it is determined depending on the number of driving circuits to be used and the number of signal lines and power lines connected to the driving circuits, so it is not limited to 8 or 12.

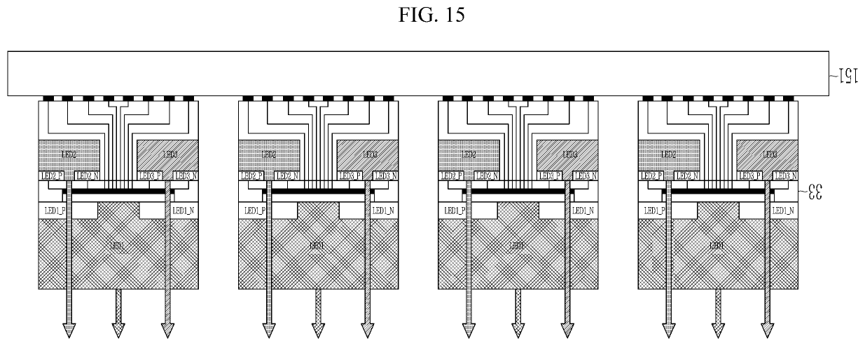

FIG. 15 is a diagram illustrating a partial package structure of an LED display device according to an exemplary embodiment.

A package according to an exemplary embodiment may not include a TFT in a backplane 151. As described in the previous exemplary embodiment, since the driving circuits and wires for driving the LED are provided in the circuit layer 33, the backplane 151 may include only metal lines for supplying signals or power voltages to the plurality of pads. As a result, it is possible to drive an LED display device having a full-color active matrix structure without TFTs for driving LEDs in the backplane.

The RGB structures may be arranged in an order and a shape that are different from those described above. In addition to the RGB subpixels, a W subpixel may be added to improve color. Pixels may be implemented in various ways, such as GB and GR structures as well as the RGB array. The LED generating material may be GaN, GaAs, or the like, but the present disclosure is not limited thereto. The substrate material is not limited to sapphire, and at least one of several materials such as GaN, GaN on Si, and SiC may be used.

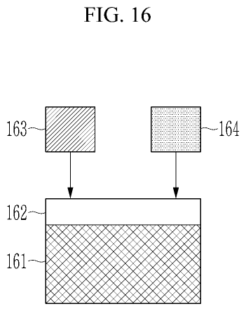

FIG. 16 is a diagram for explaining a method of manufacturing a package.

As illustrated in FIG. 16, after TFTs and metal wires 162 are formed on a green (G) LED chip 161, a red (R) LED 163 and a blue (B) LED 164 may be attached. The TFTs and metal wires 162 illustrated in FIG. 16 may include TFTs and metal wires for an RGB LED.

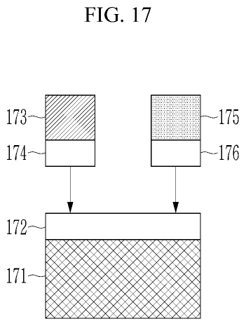

FIG. 17 is a diagram for explaining a method of manufacturing a package.

As illustrated in FIG. 17, after TFTs and metal wires 172 are formed on a green (G) LED chip 171, a structure in which a red (R) LED 173 and TFTs and metal wires 174 for the R LED are stacked and a structure in which a blue (B) LED 175 and TFTs and metal wires 176 for the B LED are stacked may be attached.

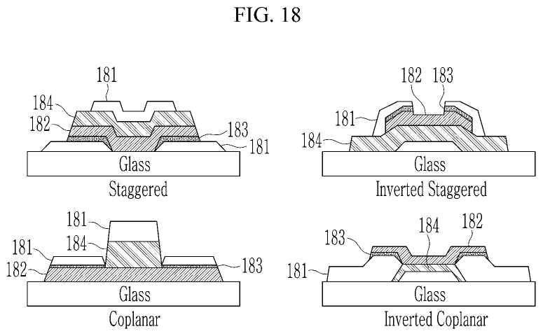

FIG. 18 is a diagram illustrating various TFT structures.

The TFT in the present disclosure may be implemented in one of the various structures illustrated in FIG. 18, but the present disclosure is not limited thereto.

As illustrated in FIG. 18, the TFT structure may be one of a staggered type, an inverted staggered type, a coplanar type, and an inverted coplanar type, depending on a position at which a gate terminal is disposed.

The TFT may include an electrode 181 located on a glass substrate, a semiconductor 182, an ohmic layer 183, and an insulator 184.

In a module structure, some or all of the portions marked as LEDs may be OLEDs, quantum dots, mini LEDs, or the like, as well as μLEDs, in another light emission scheme. For example, the LED1 may be an OLED and the LED2 and the LED3 may be μLEDs, or the LED2 and the LED3 may be OLEDs and the LED1 may be a μLED. In this case, by replacing blue OLEDs with μLEDs, it is possible to expect improvements in lifespan of blue pixels.

What is claimed is:

1. A display device comprising:
a first-color light emitting diode (LED);
a circuit layer located on the first-color LED and including a plurality of thin film transistors (TFTs) and a plurality of first wires;
a second-color LED located in a first area on the circuit layer;
a third-color LED located in a second area on the circuit layer;
a plurality of second wires located between the first area and the second area; and
a plurality of pads connected to the plurality of second wires.

2. The display device of claim 1, further comprising:
a passivation layer located on the second-color LED, the third-color LED, and the circuit layer,
wherein the plurality of pads are formed and located on the passivation layer.

3. The display device of claim 1, wherein
the plurality of TFTs and the plurality of first wires include at least two TFTs and two first wires for driving the first-color LED, and
the two first wires are connected to two electrodes of the first-color LED, respectively.

4. The display device of claim 1, wherein
the plurality of TFTs and the plurality of first wires include at least two TFTs and two first wires for driving the second-color LED, and
the two first wires are connected to two electrodes of the second-color LED, respectively.

5. The display device of claim 1, wherein
the plurality of TFTs and the plurality of first wires include at least two TFTs and two first wires for driving the third-color LED, and
the two first wires are connected to two electrodes of the third-color LED, respectively.

6. The display device of claim 1, wherein
the first-color LED overlaps with the first area in a vertical direction, and the first-color LED overlaps with the second area in the vertical direction.

7. The display device of claim 1, wherein
the first-color LED does not overlap with the first area and the second area in a vertical direction.

8. The display device of claim 1, wherein
the plurality of pads include:
two pads through which a gate signal and a data signal are supplied to the first-color LED;
two pads through which a gate signal and a data signal are supplied to the second-color LED;
two pads through which a gate signal and a data signal are supplied to the third-color LED; and
two pads through which two power supply voltages are supplied.

9. A method of manufacturing a display device, the method comprising:
forming a first LED;
forming a circuit layer including a plurality of TFTs and a plurality of first wires on the first LED;
forming a second LED in a first area of the circuit layer and forming a third LED in a second area of the circuit layer;
forming a passivation layer on the second LED, the third LED, and the circuit layer; and
forming a plurality of second wires in the passivation layer.

10. The method of claim 9, further comprising:
forming a plurality of pads connected to the plurality of second wires on the passivation layer.
